(19) United States
(12) Patent Application Publication
(10) Pub. No.: US 2023/0099262 A1
(43) Pub. Date: Mar. 30, 2023

(54) Optical engine module and projection apparatus

(71) Applicant: Coretronic Corporation, Hsin-Chu (TW)

(72) Inventors: CHENG-YU YEH, Hsin-Chu (TW); WEN-YEN CHUNG, Hsin-Chu (TW)

(21) Appl. No.: 17/947,185

(22) Filed: Sep. 19, 2022

(30) Foreign Application Priority Data
Sep. 30, 2021 (CN) 202111160104.5

(51) Int. Cl. G03B 21/16; H05K 7/20

(52) U.S. Cl. CPC G03B 21/16; H05K 7/20145; H05K 7/20172; H05K 7/20181

(57) ABSTRACT

An optical engine module is adapted to a projection apparatus. The optical engine module includes an optical engine housing, a first optical element and a heat dissipation assembly. The optical engine housing has a first vent and a second vent. The first optical element is disposed in the optical engine housing and adjacent to the first vent. The heat dissipation assembly is disposed outside the optical engine housing and adapted to generate airflow flowing through the first vent, the first optical element and the second vent. The heat dissipation assembly includes a fan and an air duct, in which the air duct is connected between the first vent and the fan. A projection apparatus having the optical engine module is also provided.

### CROSS-REFERENCE TO RELATED APPLICATION

This application claims the priority benefit of China application 202111160104.5, filed on 2021 Sep. 30. The entirety of the above-mentioned patent application is hereby incorporated by reference herein and made a part of this specification.

### FIELD OF THE INVENTION

The invention relates to an optical engine module, and more particularly to an optical engine module adapted to a projection apparatus, and a projection apparatus having the optical engine module.

### BACKGROUND OF THE INVENTION

The conventional projector roughly includes an optical engine module and a projection lens. The optical engine module usually includes a light source and optical elements, and the above-mentioned optical elements are usually arranged in a housing with better airtightness to avoid dust pollution. In addition, because the temperature of the optical element may rise by the irradiation of the light beam of the light source, the optical engine module is usually equipped with a fan to dissipate the optical element.

However, due to the high airtightness of the housing, the air inside and outside the housing is not easy to convection. Therefore, in the conventional optical engine module, the temperature of the optical elements is likely to be too high, which affects the image quality and durability of the projector.

The information disclosed in this “BACKGROUND OF THE INVENTION” section is only for enhancement understanding of the background of the invention and therefore it may contain information that does not form the prior art that is already known to a person of ordinary skill in the art. Furthermore, the information disclosed in this “BACKGROUND OF THE INVENTION” section does not mean that one or more problems to be solved by one or more embodiments of the invention were acknowledged by a person of ordinary skill in the art.

### SUMMARY OF THE INVENTION

The invention provides an optical engine module to increase heat dissipation efficiency.

The invention provides a projection apparatus with good image quality and durability.

Other advantages and objects of the invention may be further illustrated by the technical features broadly embodied and described as follows.

In order to achieve one or a portion of or all of the objects or other objects, an optical engine module provided in an embodiment of the invention includes an optical engine housing, a first optical element and a heat dissipation assembly. The optical engine housing has a first vent and a second vent. The first optical element is disposed in the optical engine housing and adjacent to the first vent. The heat dissipation assembly is disposed outside the optical engine housing and adapted to generate airflow flowing through the first vent, the first optical element and the second vent. The heat dissipation assembly includes a fan and an air duct, in which the air duct is connected between the first vent and the fan.

In order to achieve one or a portion of or all of the objects or other objects, a projection apparatus provided in an embodiment of the invention includes the above-mentioned optical engine module and a projection lens. The optical engine module is adapted to provide an image beam, and the projection lens is disposed on a transmission path of the image beam to project the image beam.

In the optical engine module of the invention, the fan is disposed outside the optical engine housing, and the fan and the first vent of the optical engine housing are connected by an air duct to concentrate the airflow generated by the fan into the optical engine housing, and then dissipate heat to the first optical element in the optical engine housing. Therefore, compared with the prior art, the optical engine module of the invention may effectively use the cold air outside the housing to dissipate heat to the first optical element, thereby increasing the heat dissipation efficiency of the optical engine module. Since the projection apparatus of the invention is disposed with the above-mentioned optical engine module, it may have good image quality and durability.

Other objectives, features and advantages of The invention will be further understood from the further technological features disclosed by the embodiments of The invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an optical engine module of one embodiment of the invention;

FIG. 2 is a schematic cross-sectional diagram of the optical engine module of FIG. 1;

FIG. 3 is a schematic diagram of an optical engine module of another embodiment of the invention;

FIG. 4 is a schematic cross-sectional diagram of the optical engine housing of FIG. 2 from another angle of view;

FIG. 5 is a three-dimensional schematic diagram of a third optical element disposed in a slot of one embodiment of the invention;

FIG. 6 is a schematic diagram of an optical engine module of another embodiment of the invention;

FIG. 7 is a schematic diagram of an optical engine module of another embodiment of the invention;

FIG. 8 is a block diagram of a projection apparatus of one embodiment of the invention;

FIG. 9 is a schematic top view of one embodiment of the projection apparatus of FIG. 8;

FIG. 10 is an internal schematic diagram of a projection apparatus of another embodiment of the invention; and

FIG. 11 is an internal schematic diagram of a projection apparatus of another embodiment of the invention.

### DETAILED DESCRIPTION OF PREFERRED EMBODIMENTS

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “front”, “back”, etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including”, “comprising”, or “having” and variations thereof herein is meant to encompass the items listed thereafter and equivalents thereof as well as additional items. Unless limited otherwise, the terms “connected”, “coupled”, and “mounted” and variations thereof herein are used broadly and encompass direct and indirect connections, couplings, and mountings. Similarly, the terms “facing”, “faces”, and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component facing “B” component directly or one or more additional components is between “A” component and “B” component. Also, the description of “A” component “adjacent to” “B” component herein may contain the situations that “A” component is directly “adjacent to” “B” component or one or more additional components is between “A” component and “B” component. Accordingly, the drawings and descriptions will be regarded as illustrative in nature and not as restrictive.

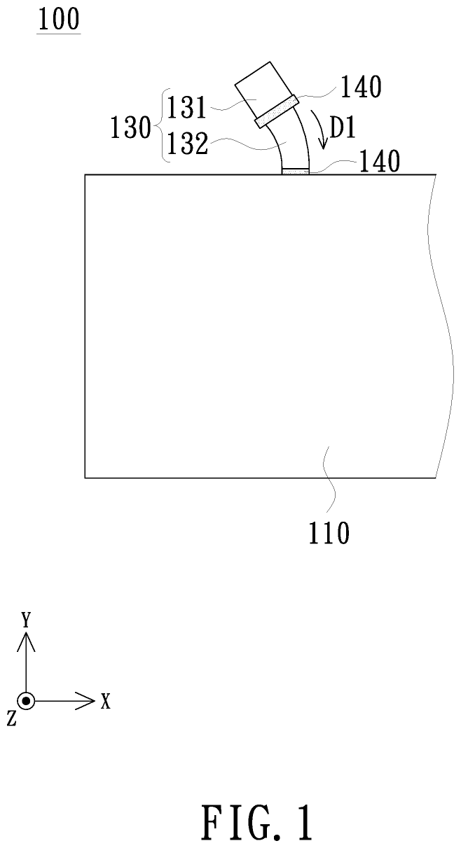

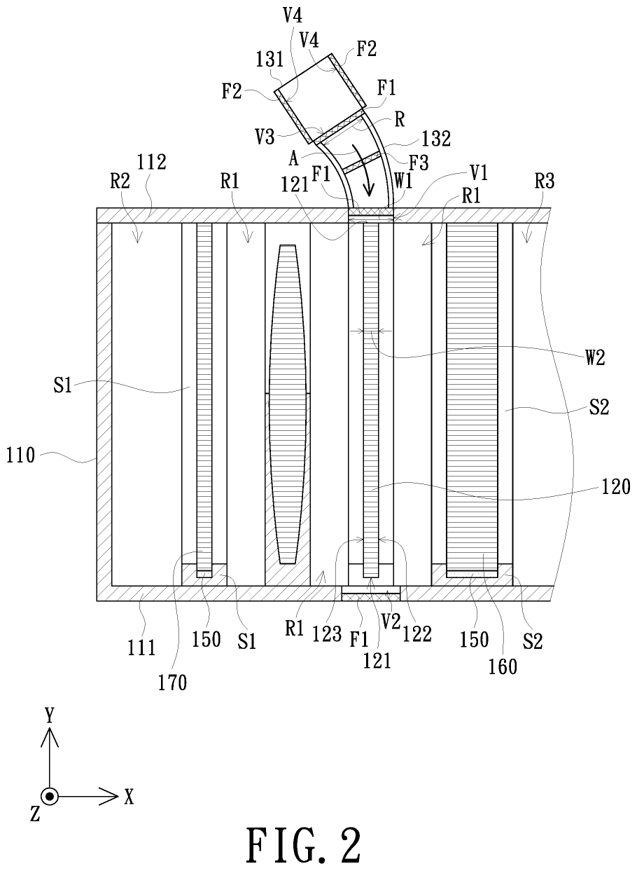

FIG. 1 is a schematic diagram of an optical engine module of one embodiment of the invention. FIG. 2 is a schematic cross-sectional diagram of the optical engine module of FIG. 1. Referring to FIG. 1 and FIG. 2, an optical engine module 100 may be used in a projection apparatus. The optical engine module 100 includes an optical engine housing 110, a first optical element 120 and a heat dissipation assembly 130. The optical engine housing 110 has a first vent V1 and a second vent V2. The first optical element 120 is disposed in the optical engine housing 110 and adjacent to the first vent V1. The heat dissipation assembly 130 is disposed outside the optical engine housing 110 and adapted to generate airflow A flowing through the first vent V1, the first optical element 120 and the second vent V2. The heat dissipation assembly 130 includes a fan 131 and an air duct 132, in which the air duct 132 is connected between the first vent V1 and the fan 131. Specifically, the airflow A is generated by the fan 131, and the air duct 132 guides the airflow A into the optical engine housing 110.

Continuing to refer to FIG. 2, a temperature of the first optical element 120 may rise by the irradiation of the light beam, and the heat dissipation component 130 may dissipate heat to the first optical element 120. The first optical element 120 of the embodiment may include a polarizing splitting convertor. However, in one embodiment, the first optical element 120 may also include other optical elements that are easy to heat up, and the invention does not limit thereto. In the embodiment, the first optical element 120 may have a side surface 121, a light incident side 122, and a light exit side 123, in which FIG. 2 marks a partial side surface 121 facing the first vent V1 and the second vent V2. The side surface 121 is connected between the light incident side 122 and the light exit side 123. The first vent V1 is opposite to the second vent V2. The first optical element 120 is located between the first vent V1 and the second vent V2, and the side surface 121 of the first optical element 120 is opposite to the first vent V1 and the second vent V2. In this way, the airflow A entering the optical engine housing 110 from the first vent V1 flows through the light incident side 122 and the light exit side 123 at the same time, and dissipates heat to the light incident side 122 and the light exit side 123 at the same time, so as to increase the heat dissipation efficiency. Furthermore, in a direction from the light incident side 122 to the light exit side 123, a width W1 of the first vent V1 is, for example, greater than a width W2 of the side 121 to further ensure that the airflow A flows through the light incident side 122 and the light exit side 123, thereby further increasing the heat dissipation efficiency.

The fan 131 includes, for example, a blower fan 131, but the fan 131 in other embodiments may also include an axial fan.

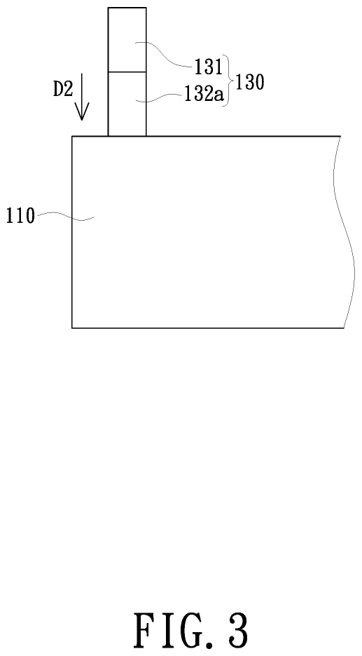

An inner diameter R of the air duct 132 is tapered, for example, from one end connected to the fan 131 toward another end connected to the first vent V1, so that the airflow A may blow the first optical element 120 more concentratedly, thereby increasing the heat dissipation efficiency. In addition, in the embodiment, an axial direction of the air duct 132 may extend along an arc direction D1. In this way, the wind resistance of the airflow A flowing in the air duct 132 may be reduced, and the utilization rate of the airflow A may be increased. In another embodiment, such as shown in FIG. 3, the axial direction of the air duct 132a may also extend along a linear direction D2, so that the wind resistance may be further reduced, the utilization rate of the airflow may be further increased, and the space required for the configuration of the air duct 132a may be reduced. Referring to FIG. 1 and FIG. 2 together, the optical engine module 100 may further include at least one airtight member, and the embodiment uses two airtight members 140 as an example. The airtight member 140 is sealed between the air duct 132 and the optical engine housing 110 and between the air duct 132 and the fan 131 to increase the air tightness between the optical engine housing 110, the air duct 132 and the fan 131. Therefore, the airtight member 140 may increase the utilization rate of the airflow A and reduce the amount of dust entering the optical engine housing 110. In one embodiment, the quantity of the airtight member 140 may be one, and it is sealed between the air duct 132 and the optical engine housing 110 or between the air duct 132 and the fan 131. However, the invention does not limit the specific quantity of the airtight member 140. Incidentally, the airtight member 140 of the embodiment may surround the connection between the air duct 132 and the optical engine housing 110 and the connection between the air duct 132 and the fan 131, but other embodiments are not limited thereto. In addition, a material of the airtight member 140 of the embodiment includes rubber, for example, but the invention is not limited thereto.

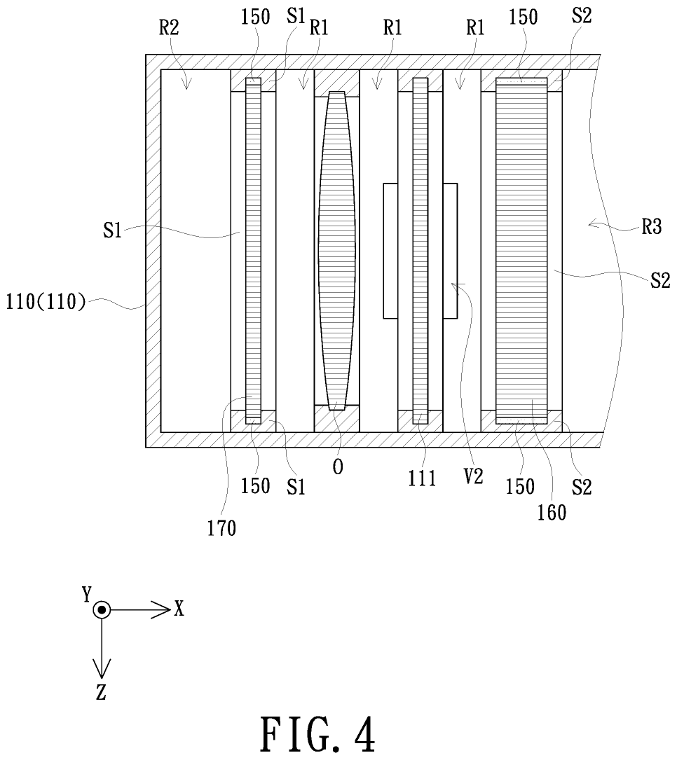

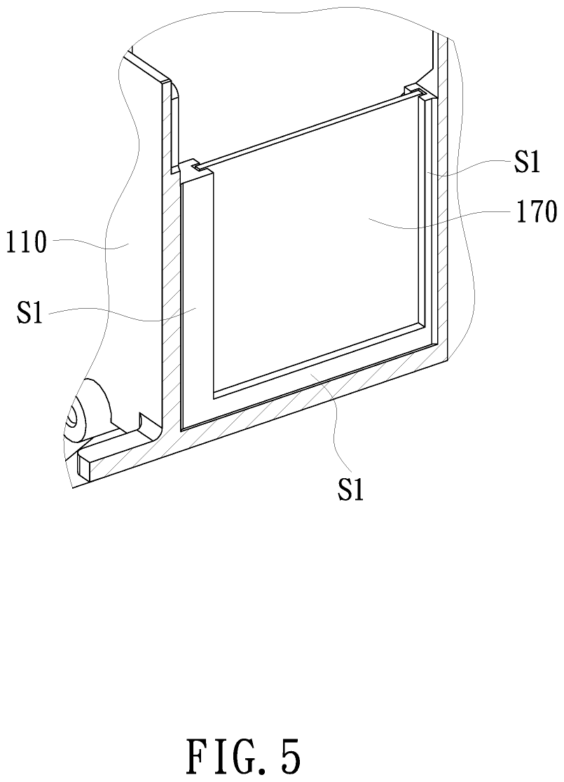

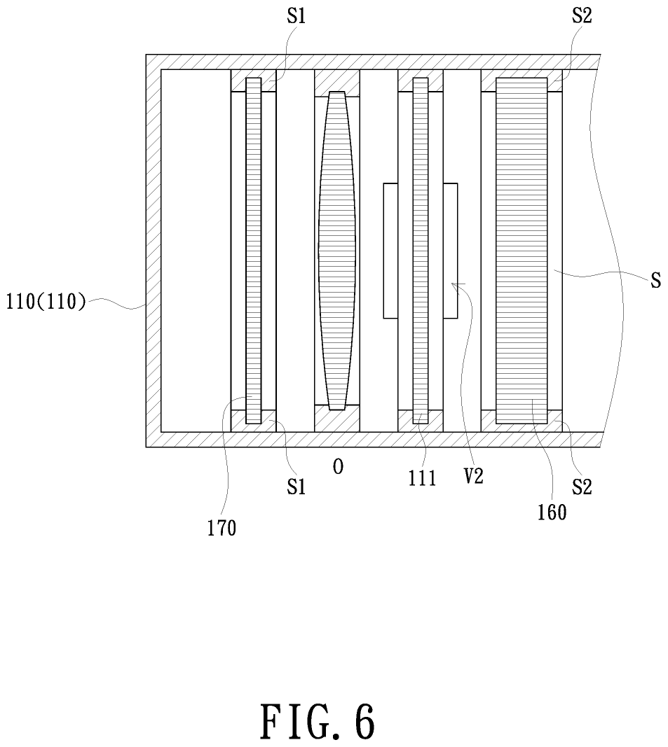

FIG. 4 is a schematic cross-sectional diagram of the optical engine housing of FIG. 2 from another angle of view, in which the relationship of the angle of view between FIG. 1, FIG. 2 and FIG. 4 is indicated by the directions X, Y, and Z. Referring to FIG. 2 and FIG. 4, the optical engine module 100 may further include two dustproof members 150, a second optical element 160 and a third optical element 170. The second optical element 160 and the third optical element 170 are disposed in the optical engine housing 110, and the first optical element 120 is disposed between the second optical element 160 and the third optical element 170. The two dustproof members 150 are sealed between the second optical element 160 and the optical engine housing 110 and between the third optical element 170 and the optical engine housing 110, so that a cavity R1 where the first optical element 120 is located may be airtight with the other cavities R2 and R3 in the optical engine housing 110, thereby preventing dust from entering the other cavities R2 and R3. The dustproof member 150 may include sponge or rubber, but is not limited thereto. In addition, the optical engine housing 110 may have slots S1 and S2, and the dustproof members 150 are respectively disposed in the slots S1 and S2 to further prevent dust from entering the other cavities R2 and R3 from the cavity R1. For example, the optical engine housing 110 of the embodiment may include a main body 111 and a cover plate 112, in which the slots S1 and S2 may be disposed in the main body 111, and the dustproof members 150 are sealed between the second optical element 160 and the slot S2 and between the third optical element 170 and the slot S1. Furthermore, referring to FIG. 5, FIG. 5 is a three-dimensional schematic diagram of a third optical element disposed in a slot of one embodiment of the invention. A shape of the optical engine housing 110 may be similar to a rectangular cavity, and a shape of the second optical element 160 (drawn in FIG. 4) and a shape of the third optical element 170 are similar to a rectangular plate. FIG. 5 takes the third optical element 170 as an example. The shape of the second optical element 160 is substantially similar to that of the third optical element 170. Since the shape of the second optical element 160 and the shape of the third optical element 170 are more suitable for the shape of the optical engine housing 110, the second optical element 160 and the third optical element 170 are selected to be disposed in the slots S1 and S2 (the slot S2 is drawn in FIG. 4), which may further increase the air tightness effect. However, in one embodiment, different optical elements may also be selected to increase the air tightness effect according to other factors, and the invention does not limit thereto. In another embodiment, such as FIG. 6, the second optical element 160 and the third optical element 170 may be respectively disposed in the slots S1 and S2, and the dustproof members 150 of FIG. 4 are not respectively sealed between the second optical element 160 and the slot S2 and between the third optical element 170 and the slot S1.

Referring to FIG. 2 again, the optical engine module 100 further includes, for example, at least one filter, and the filters F1, F2 and F3 are used as examples in the embodiment. The positions of the filters F1, F2 and F3 are as follows. The filter F1 may be disposed between the air duct 132 and the first vent V1, between the air duct 132 and the fan 131, and on the second vent V2 to reduce the amount of dust entering the optical engine housing 110. Since the filter F1 would increase the wind resistance, in one embodiment, the quantity of the filter F1 may be appropriately reduced. For example, the filter F1 may be optionally disposed between the air duct 132 and the first vent V1, between the air duct 132 and the fan 131, or on the second vent V2 to moderately reduce the wind resistance. The invention does not limit the specific quantity of the filter F1. In addition, the fan 131 has a third vent V3 and a fourth vent V4 communicating with each other, and the embodiment is exemplified by two fourth vents V4. The air duct 132 is connected to the third vent V3, and the filter F2 may be disposed on the fourth vent V4. In addition, the filter F3 may be disposed in the air duct 132. Similarly, the specific quantities of the filters F2 and F3 may be determined according to the size of the wind resistance and the dustproof effect, and are not limited to those shown in FIG. 2.

Compared with the prior art, in the optical engine module 100 of the embodiment, the fan 131 is disposed outside the optical engine housing 110, and the fan 131 and the first vent V1 of the optical engine housing 110 are connected by an air duct 132 to concentrate the airflow A generated by the fan 131 into the optical engine housing 110, and then dissipate heat to the first optical element 120 in the optical engine housing 110. Therefore, compared with the prior art, the optical engine module 100 of the invention may effectively use the cold air outside the housing to dissipate heat to the first optical element 120, thereby increasing the heat dissipation efficiency of the optical engine module 100.

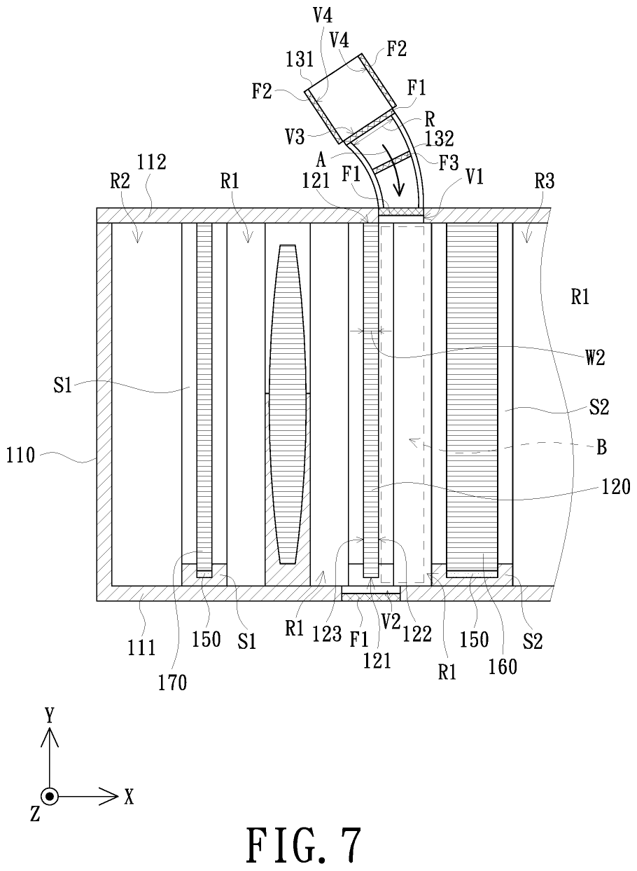

FIG. 7 is a schematic diagram of an optical engine module of another embodiment of the invention. In the optical engine housing 110a of the embodiment, the positions of the first vent V1 and the second vent V2 may be different from those of the embodiment of FIG. 1 due to factors such as component layout. Referring to the optical engine module 100a of FIG. 7, the first optical element 120 is located between the first vent V1 and the second vent V2. The light incident side 122 may be close to and face an area between the first vent V1 and the second vent V2, such as the area B in FIG. 7. In detail, since the temperature of the light incident side 122 is higher than that of the light exit side 123, the positions of the first vent V1 and the second vent V2 may be selected to be closer to the light incident side 122, so that the airflow A generated by the fan 131 would flow through the light incident side 122 from the area B, thereby dissipating heat to the light incident side 122 with a higher temperature.

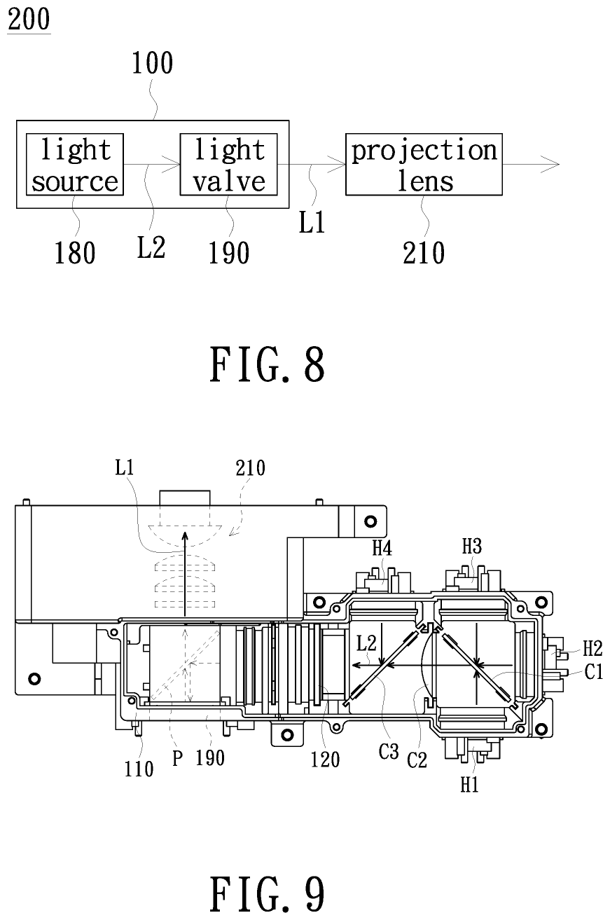

FIG. 8 is a block diagram of a projection apparatus of one embodiment of the invention. FIG. 9 is a schematic top view of one embodiment of the projection apparatus of FIG. 8. Referring to FIG. 8 and FIG. 9, the projection apparatus 200 includes the above-mentioned optical engine module 100 and a projection lens 210. The optical engine module 100 is adapted to provide an image beam L1. The projection lens 210 is disposed on a transmission path of the image beam L1 to project the image beam L1.

In the embodiment, referring to FIG. 9, the optical engine module 100 may further include a light source 180 and a light valve 190, in which the light source 180 includes four light-emitting elements H1, H2, H3 and H4 and light converging elements C1, C2 and C3. In detail, the light source 180 forms the illumination beam L2. The first optical element 120 is disposed between the light source 180 and the light valve 190 on a transmission path of the illumination beam L2. The illumination beam L2 may be transmitted to the light valve 190 through the first optical element 120. Further, the light converging elements C1 and C3 include, for example, a dichroic mirror, and the light converging element C2 includes, for example, a condensing lens, but other embodiments are not limited thereto. It can be understood that the positions and the structures of the light converging elements C1, C2 and C3 in the figures are only examples, and the invention does not limit thereto. In the embodiment, the light beams generated by the four light-emitting elements H1, H2, H3 and H4 are transmitted through the light converging elements C1, C2 and C3 to synthesize the illumination beam L2. In the embodiment, the light-emitting element H1 may be, for example, a green light-emitting module. The light-emitting element H2 may be, for example, a blue light-emitting diode (LED). The light-emitting element H3 may be, for example, a blue light-emitting diode. The light-emitting element H4 may be, for example, a red light-emitting diode. The green light-emitting module of the light-emitting element H1 may include a blue light-emitting diode and a phosphor layer. The phosphor layer may be disposed between the blue light-emitting diode of the light-emitting element H1 and the light converging element C1, and the phosphor layer may convert blue light into green light. One side of the phosphor layer receives a blue light beam from the blue light-emitting diode of the light-emitting element H1, and the other side receives the blue light beam from the light-emitting element H3 and converts the blue light beam into a green light beam, which may increase the intensity of the green light beam.

The light valve 190 of the embodiment may convert the illumination beam L2 into the image beam L1. In the embodiment in which the first optical element 120 includes a polarizing splitting converter, the light valve 190 adopts, for example, a structure of a liquid crystal on silicon (LCoS) panel or a transmissive liquid crystal panel. For example, the first optical element 120 of FIG. 9 includes, for example, a polarizing splitting convertor, and the light valve 190 may include a liquid crystal on silicon. In addition, the optical engine module 100 of the embodiment may further include a polarizing beam splitter (PBS) P. In detail, the illumination beam L2 passing through the first optical element 120 may be incident to the polarizing beam splitter P, reflected by the polarizing beam splitter P to the light valve 190, and then reflected by the light valve 190 to pass through the polarizing beam splitter P. Furthermore, a polarization direction of the light beam would be changed after exiting from the light valve 190, so the light beam exiting from the light valve 190 may pass through the polarization beam splitter P. In another embodiment, an optical wave plate may also be provided to change the polarization direction of the light beam. The structure of the light valve 190 is not limited to that shown in the embodiment. For example, in one embodiment, the light valve 190 may adopt the structure of a digital micromirror device (DMD), and the first optical element 120 may include an optical element that is easy to heat up under this structure, such as a polarizing splitting converter, a condenser lens or a polarization beam splitter, and the invention does not limit thereto. In addition, the embodiment does not limit the quantity of light valve 190. For example, in the embodiment in which the light valve 190 adopts the liquid crystal display panel structure, the projection apparatus 200 may adopt the structure of a single-sheet liquid crystal display panel or a three-sheets liquid crystal display panel, but is not limited thereto. It can be understood that, in other embodiments, the specific structure of the light source 180 may be adapted to the light valve 190 of different structures, and is not limited to the light-emitting elements H1, H2, H3 and H4 shown in FIG. 9.

In the embodiment, the projection lens 210 includes, for example, one or more optical lenses, and the embodiment is exemplified by a plurality of optical lenses. The diopter of the optical lenses may be the same or different from each other. For example, the optical lens may include various non-planar lenses such as bi-concave lenses, bi-convex lenses, meniscus lenses, convex-concave lenses, plano-convex lenses, and plano-concave lenses, or any combination of the above non-planar lenses. On the other hand, the projection lens 210 may also include a flat optical lens. The invention does not limit the specific structure of the projection lens 210. Incidentally, the optical engine housing 110 of the embodiment partially extends out for the projection lens 210 to be disposed therein. However, in other embodiments, the housing where the projection lens 210 is disposed and the housing where the light valve 190 is disposed are not limited to be integrally formed.

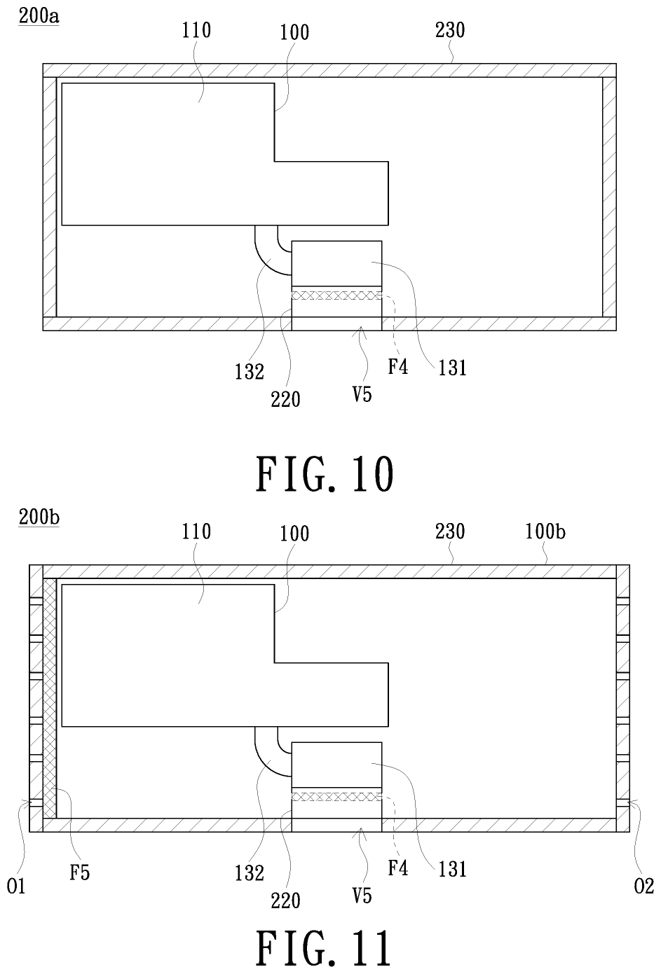

FIG. 10 is an internal schematic diagram of a projection apparatus of another embodiment of the invention. Referring to FIG. 10, the projection apparatus 200a may further include a wind duct 220 and a projection apparatus housing 230, in which the projection apparatus housing 230 in FIG. 10 is shown in a cross-sectional view. The optical engine module 100 is located in the projection apparatus housing 230. The projection apparatus housing 230 has a vent hole V5, and the vent hole V5 is disposed corresponding to the fan 131. The wind duct 220 is connected between the vent hole V5 and the fan 131 to reduce the amount of dust entering the optical engine housing 110 from the fan 131 and the air duct 132 and increase the utilization rate of airflow. In addition, the projection apparatus 200a may further include a filter F4. The filter F4 is disposed in the wind duct 220 to further reduce the amount of dust entering the optical engine housing 110. It can be understood that, the filter F4 may also be disposed at other positions of the projection apparatus 200a. For example, in the projection apparatus 200b shown in FIG. 11, the filter F4 may also be disposed on the vent hole V5, so that the filter F4 also has the advantage of being easy to replace.

The projection apparatus 200b further includes, for example, a filter F5. The projection apparatus housing 230 has a first heat dissipation hole O1 and a second heat dissipation hole O2 that communicate with each other. The optical engine module 100 is located in the projection apparatus housing 230 and between the first heat dissipation hole O1 and the second heat dissipation hole O2. The filter is disposed on the first heat dissipation hole O1 and/or the second heat dissipation hole O2, and the embodiment takes the filter disposed in the first heat dissipation hole O1 as an example. Specifically, a fan (not shown) may be disposed beside the first heat dissipation hole O1 and the second heat dissipation hole O2 to dissipate heat inside the projection apparatus housing 230. Incidentally, the projection apparatus 200b of the embodiment may also be provided with the wind duct 220 and the filter F4 shown in FIG. 10, but the invention is not limited thereto.

Compared with the prior art, since the projection apparatus of the invention is disposed with the above-mentioned optical engine module, it may have good image quality and durability. In addition, the filters F4 and F5 may reduce the amount of dust entering the optical engine housing 110 and the projection apparatus housing 230, and the wind duct 220 may further increase the heat dissipation efficiency of the optical engine module 100.

In summary, in the optical engine module of the invention, the fan is disposed outside the optical engine housing, and the fan and the first vent of the optical engine housing are connected by an air duct to concentrate the airflow generated by the fan into the optical engine housing, and then dissipate heat to the first optical element in the optical engine housing. Therefore, compared with the prior art, the optical engine module of the invention may effectively use the cold air outside the housing to dissipate heat to the first optical element, thereby increasing the heat dissipation efficiency of the optical engine module. Since the projection apparatus of the invention is disposed with the above-mentioned optical engine module, it may have good image quality and durability.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “The invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the disclosure is intended to be dedicated to the public regardless of whether the element or component is explicitly recited in the following claims. Furthermore, the terms such as the first optical element, the second optical element, the third optical element, the first heat dissipation hole, the second heat dissipation hole, the first vent, the second vent, the third vent and the fourth vent are only used for distinguishing various elements and do not limit the number of the elements.

What is claimed is:

1. An optical engine module, adapted to a projection apparatus, the optical engine module comprising:
an optical engine housing, having a first vent and a second vent;
a first optical element, disposed in the optical engine housing and adjacent to the first vent; and
a heat dissipation assembly, disposed outside the optical engine housing and adapted to generate airflow flowing through the first vent, the first optical element and the second vent, wherein the heat dissipation assembly comprises a fan and an air duct, and the air duct is connected between the first vent and the fan.

2. The optical engine module according to claim 1, wherein the first optical element has a side surface, a light incident side, and a light exit side, the side surface is connected between the light incident side and the light exit side, the first vent is opposite to the second vent, the first optical element is located between the first vent and the second vent, and the side surface of the first optical element is opposite to the first vent and the second vent.

3. The optical engine module according to claim 2, wherein in a direction from the light incident side to the light exit side, a width of the first vent is greater than a width of the side surface.

4. The optical engine module according to claim 1, wherein the first optical element has a light incident side and a light exit side opposite to each other, the first vent is opposite to the second vent, the first optical element is located between the first vent and the second vent, and the light incident side is close to and faces an area between the first vent and the second vent.

5. The optical engine module according to claim 1, further comprising two dustproof members, a second optical element and a third optical element, wherein the second optical element and the third optical element are disposed in the optical engine housing, the first optical element is disposed between the second optical element and the third optical element, and the two dustproof members are respectively sealed between the second optical element and the optical engine housing and between the third optical element and the optical engine housing.

6. The optical engine module according to claim 5, wherein the optical engine housing has two slots, and the two dustproof parts are respectively disposed in the two slots.

7. The optical engine module according to claim 1, further comprising a second optical element and a third optical element, wherein the optical engine housing has two slots, the second optical element and the third optical element are respectively disposed in the two slots, and the first optical element is disposed between the second optical element and the third optical element.

8. The optical engine module according to claim 1, further comprising at least one filter, disposed between the air duct and the first vent.

9. The optical engine module according to claim 1, further comprising at least one filter, disposed between the air duct and the fan.

10. The optical engine module according to claim 1, further comprising at least one filter, disposed on the second vent.

11. The optical engine module according to claim 1, further comprising a filter, wherein the fan has a third vent and a fourth vent communicating with each other, the air duct is connected to the third vent, and the filter is disposed on the fourth vent.

12. The optical engine module according to claim 1, further comprising a filter, disposed in the air duct.

13. The optical engine module according to claim 1, further comprising at least one airtight member, sealed between the air duct and the optical engine housing.

14. The optical engine module according to claim 1, further comprising at least one airtight member, sealed between the air duct and the fan.

15. The optical engine module according to claim 1, wherein an inner diameter of the air duct is tapered from one end connected to the fan toward another end connected to the first vent.

16. The optical engine module according to claim 1, wherein an axial direction of the air duct extends along a linear direction or an arc direction.

17. The optical engine module according to claim 1, wherein the fan comprises a blower fan.

18. The optical engine module according to claim 1, wherein the first optical element comprises a polarizing splitting convertor.

19. A projection apparatus, comprising an optical engine module and a projection lens, the optical engine module being adapted to provide an image beam, and the projection lens being disposed on a transmission path of the image beam to project the image beam, wherein the optical engine module comprises:
an optical engine housing, having a first vent and a second vent;
a first optical element, disposed in the optical engine housing and adjacent to the first vent; and
a heat dissipation assembly, disposed outside the optical engine housing and adapted to generate airflow flowing through the first vent, the first optical element and the second vent, wherein the heat dissipation assembly comprises a fan and an air duct, and the air duct is connected between the first vent and the fan.

20. The projection apparatus according to claim 19, further comprising a filter and a projection apparatus housing, wherein the optical engine module is located in the projection apparatus housing, the projection apparatus housing has a vent hole corresponding to the fan, and the filter is disposed on the vent hole.

21. The projection apparatus according to claim 19, further comprising a wind duct and a projection apparatus housing, wherein the optical engine module is located in the projection apparatus housing, the projection apparatus housing has a vent hole corresponding to the fan, and the wind duct is connected between the vent hole and the fan.

22. The projection apparatus according to claim 21, further comprising a filter, disposed in the wind duct.

23. The projection apparatus according to claim 19, further comprising a filter and a projection apparatus housing, wherein the projection apparatus housing has a first heat dissipation hole and a second heat dissipation hole communicated with each other, the optical engine module is located in the projection apparatus housing and between the first heat dissipation hole and the second heat dissipation hole, the filter is disposed on the first heat dissipation hole.

24. The projection apparatus according to claim 19, further comprising a filter and a projection apparatus housing, wherein the projection apparatus housing has a first heat dissipation hole and a second heat dissipation hole communicated with each other, the optical engine module is located in the projection apparatus housing and between the first heat dissipation hole and the second heat dissipation hole, the filter is disposed on the second heat dissipation hole.
